(19) United States
(12) Patent Application Publication
(10) Pub. No.: US 2024/0371846 A1
(43) Pub. Date: Nov. 7, 2024

(54) OPTOELECTRONIC DEVICE AND METHOD FOR MANUFACTURE

(71) Applicant: ams-OSRAM International GmbH, Regensburg (DE)

(72) Inventors: Dirk Becker, Lanqquaid (DE); Michael Zitzlsperger, Regensburg (DE)

(21) Appl. No.: 18/690,256

(22) PCT Filed: Sep. 12, 2022
(86) PCT No.: PCT/EP2022/075259

§ 371 Date: Mar. 7, 2024

(30) Foreign Application Priority Data
Sep. 13, 2021 (DE) 10 2021 123 663.0

(51) Int. Cl. H01L 25/16; H01L 33/62

(52) U.S. Cl. CPC H01L 25/167; H01L 33/62; H01L 2933/0066

(57) ABSTRACT

In an embodiment an optoelectronic device includes a lead frame with a first metallic region and at least one second metallic region spaced therefrom, wherein the first metallic region and the at least one second metallic region form a first cavity on a first side of the lead frame, at least one electrical component, which is arranged in the first cavity and molded with a mold compound, and which electrically connects the first metallic region and the at least one second metallic region to one another, and at least one optoelectronic component, wherein the second side is formed by a first outer side of the lead frame and the first side is formed by a side lying within the lead frame, and wherein the first cavity is formed by a cavity, which extends from the first side of the lead frame in a direction of a second outer side of the lead frame opposite the first outer side.

### CROSS-REFERENCE TO RELATED APPLICATIONS

This patent application is a national phase filing under section 371 of PCT/EP2022/075259, filed Sep. 12, 2022, which claims the priority of German patent application 10 2021 123 663.0, filed Sep. 13, 2021, each of which is incorporated herein by reference in its entirety.

### TECHNICAL FIELD

The present invention relates to an optoelectronic device, in particular a leadframe comprising at least one electrical component and at least one optoelectronic component, and to a method for manufacturing an optoelectronic device, in particular a leadframe comprising at least one electrical component and at least one optoelectronic component.

### BACKGROUND

The most commonly used substrate technologies for applying optoelectronic components are:
1) PCB substrates
2) Ceramic substrates
3) Leadframe-based substrates

In practice, further electrical components are only built into PCB substrates in the bulk material. However, wire bonding for the electrical connection of these components is generally not an option, as the PCB substrates are so heavily compressed during the manufacturing process that the wire bonds can be damaged. The embedding of electrical components (such as semiconductor chips) is not possible with ceramic substrates and not possible or only possible to a limited extent with leadframe-based substrates known to date. Complex interconnection in or on the leadframe-based substrates is therefore practically impossible.

Leadframe-based substrates for optoelectronic components, however, have many advantages over other technologies, but are currently limited in the fineness of their structures and offer no possibility of rewiring, for example to enable complex interconnection in or on the leadframe-based substrates.

### SUMMARY

Embodiments provide an optoelectronic device, in particular a leadframe comprising at least one electrical component and at least one optoelectronic component, which counteracts at least one of the aforementioned problems. Further embodiments provide a method for manufacturing an optoelectronic device, in particular a leadframe comprising at least one electrical component and at least one optoelectronic component, which counteracts at least one of the aforementioned problems.

The starting point is to supplement a leadframe-based substrate, in particular a QFN substrate (Quad Flat No Leads Package), with at least one electrical component embedded in the mold compound of the substrate. This allows additional functions, such as an ESD diode or a series resistor, to be integrated into the substrate in a very space-saving manner.

The optoelectronic device comprises, in addition to a lead frame with a first metallic region and at least one second metallic region spaced therefrom, at least one electrical component which is arranged in a first cavity of the lead frame and is molded with a mold compound. The first cavity is formed by the first and the at least one second metallic region on a first side of the lead frame. The at least one electrical component is arranged in the first cavity in such a way that it electrically connects the first metallic region and the at least one second metallic region to one another. Furthermore, at least one optoelectronic component is arranged on a second side of the lead frame facing away from the first cavity and electrically connects the first metallic region and the second metallic region to one another. Alternatively, the at least one optoelectronic component can be arranged on a second side of the lead frame facing away from the first cavity and electrically connect the first metallic region and a third metallic region to one another.

In particular, the at least one electrical component is embedded in the mold compound in a cavity of the lead frame, which connects the metallic areas of the lead frame to one another. The at least one optoelectronic component is also arranged on at least two of the metallic areas of the lead frame, in particular on a different level than the at least one electrical component. In this way, several different components can be arranged and electrically connected at different levels on or in the leadframe in order to enable more complex interconnections in or on leadframe-based substrates.

The leadframe substrate or the metallic regions of the leadframe and the mold compound may have been applied in several steps and in particular in steps or layers, so that at least a first leadframe layer with a first metallic region and at least one second metallic region spaced therefrom form a first cavity on a first side of the first leadframe layer, in which at least one electrical component is arranged. The at least one electrical component is arranged in the cavity in such a way that it electrically connects the first metallic region and the at least one second metallic region to one another and is embedded in a mold compound. According to a first embodiment example, at least one optoelectronic component can be arranged on a second side of the first leadframe layer facing away from the first cavity and electrically connect the first metallic region and the second metallic region to one another. Alternatively, according to a second embodiment example, at least one second leadframe layer can be arranged on the first side of the first leadframe layer, which also has metallic regions, some of which are in electrically conductive connection with, for example, the first metallic region or the second metallic region. The second leadframe layer may also have metallic regions which are not in electrically conductive connection with metallic regions of the first and second leadframe layers, for example a third metallic region. The at least one optoelectronic component can then be arranged on a side of the second leadframe layer facing away from the first cavity, and electrically connect the first metallic region and the third metallic region to one another.

In some embodiments, the mold compound is formed by an electrically insulating material and mechanically connects the first and the at least one second metallic region or, in particular, all metallic regions of the optoelectronic device to one another. The mold compound can, for example, be formed by a plastic or an epoxy. Preferably, the mold compound is characterized by a high thermal conductivity in order to transport the heat generated during operation of the device to the outside in the best possible way. For this purpose, the mold compound can be filled with a material or comprise particles that improve the thermal conductivity of the mold compound.

In some embodiments, the mold compound is formed by a non-transparent material, in particular a light-absorbing material.

In some embodiments, the mold compound completely fills the first cavity and is substantially flush with the first side of the lead frame. The first side of the lead frame may be formed by an outer side of the lead frame or by a side of the lead frame located inside the lead frame, in particular an imaginary side of the lead frame. The latter can be the case in particular if the optoelectronic device comprises several leadframe layers. The first side of the leadframe can then be formed by an “outer side” of the first leadframe layer, for example, on which a further leadframe layer is formed. In the final version, this may no longer be recognizable or only with difficulty, but what is essential in such a design is that a recess or even an open cavity can be formed by this structure.

In some embodiments, the at least one electrical component comprises at least one of
a series resistor;
an ESD protection diode;
a zero resistor;
an RFID chip; and
of an integrated circuit.

Additional functions can be provided by such components, which are additionally mounted in or on the lead frame, such as an ESD diode to protect against overvoltages and unauthorized voltages, or a series resistor to limit the electrical voltage on or the electrical current to permissible values by one or more components connected in series with the series resistor.

In some embodiments, the at least one optoelectronic component is formed by a light-emitting component which is designed to emit light of a specific wavelength during operation of the light-emitting component. For example, the optoelectronic component may comprise an LED (light emitting diode) or an OLED (organic light emitting diode). Alternatively or additionally, the optoelectronic component can also comprise a sensor, for example an optical sensor.

In some embodiments, the first and second sides of the lead frame are formed by two opposite outer sides of the lead frame. This applies in particular in the case where the lead frame is essentially formed by only one lead frame layer, and the first and second sides of the lead frame or of the first lead frame layer thus form opposite outer sides of the lead frame.

In some embodiments, the second side of the lead frame is formed by a first outer side of the lead frame and the first side is formed by a side located inside the lead frame. This applies in particular in the case where the lead frame has at least two lead frame layers arranged one above the other, wherein the second side of the lead frame is formed by an outer side of the second lead frame layer facing away from the first cavity, and the first side of the lead frame is formed by a side or surface between the two lead frame layers arranged one above the other.

In some embodiments, the first cavity is formed by a cavity extending from the first side of the lead frame towards a second outer side of the lead frame opposite the first outer side. This applies in particular in the case where the lead frame has at least two lead frame layers arranged one above the other, and the first cavity extends from the side or surface between the two lead frame layers arranged one above the other in the direction of the first lead frame layer and is at least partially covered by metallic regions of the second lead frame layer.

In some embodiments, a third metallic region is arranged at a distance from the first metallic region on the mold compound. This applies in particular in the event that the lead frame has at least two lead frame layers arranged one above the other, and the second lead frame layer has a metallic region which is formed in the region of the cavity on the first lead frame layer.

In some embodiments, the optoelectronic device comprises a fourth metallic region spaced apart from the third metallic region. The fourth metallic region may, for example, be formed by a metallic region which is not in electrically conductive connection with the first, second and third metallic regions and may, for example, be arranged on the mold compound at a distance from the third metallic region. In the event that the lead frame has at least two lead frame layers arranged one above the other, the fourth metallic area can be formed, for example, by a metallic area of the second lead frame layer. The fourth metallic region, on the other hand, can also form the first cavity together with the first and second metallic regions and, in the event that the lead frame has at least two lead frame layers arranged one above the other, can be formed by metallic regions of the first and second lead frame layers lying one above the other and in electrical contact with one another.

A further optoelectronic component can be arranged on the third metallic area and the fourth metallic area and connect them electrically to one another. Furthermore, the optoelectronic device can have further metallic areas and further optoelectronic components, which are arranged on the further metallic areas and electrically connect them to one another. The optoelectronic components can either be electrically connected to each other in series or in parallel, or they can be electrically contactable independently of each other.

In some embodiments, the at least one electrical component and the at least one optoelectronic component are connected in series with one another. This can apply in particular in the event that the electrical component is a series resistor.

However, the at least one electrical component and the at least one optoelectronic component can also be connected in parallel. This can apply in particular if the electrical component is an ESD protection diode.

In some embodiments, the optoelectronic device has a first and a second contact surface on an outer side of the lead frame opposite the second side, via which the optoelectronic device can be electrically connected. This allows the optoelectronic device to be surface-mounted. In the event that the lead frame has at least two lead frame layers arranged one above the other, the first and second contact surfaces can be arranged on the side of the first lead frame layer facing away from the second lead frame layer, and thus on an outer side of the lead frame facing away from the second lead frame layer.

In some embodiments, the at least one electrical component electrically connects the first metallic region and the at least one second metallic region via a bonding wire. On the other hand, the at least one electrical component can also connect the first metallic region and the at least one second metallic region by being arranged on a respective bond pad on the first metallic region and the second metallic region and being electrically connected thereto. However, the at least one electrical component can also be bonded, for example by means of an electrically conductive adhesive.

A method for manufacturing an optoelectronic device comprises the steps of:
Providing a metallic substrate with at least a first cavity on a first side of the substrate;
Arranging at least one electrical component in the first cavity;
Molding the at least one electrical component in the first cavity with a mold compound, in particular in such a way that the cavity is substantially filled with the mold compound;
Creating at least one second cavity on a second side of the substrate opposite the first side, such that a first metallic region and at least one second metallic region spaced therefrom are formed by the at least one first cavity and the at least one second cavity, and the at least one electrical component electrically connects the first metallic region and the at least one second metallic region; and
Arranging at least one optoelectronic component on at least the first metallic region in such a way that the at least one optoelectronic component electrically connects the first metallic region and the second metallic region on a side of the metallic substrate facing away from the first cavity; or in such a way that the at least one optoelectronic component electrically connects the first metallic region and a third metallic region on a side of the metallic substrate facing away from the first cavity.

In some embodiments, the method comprises, in a further step, applying at least one structured metallic layer to the first side of the substrate, wherein the structured metallic layer comprises at least one electrically insulated region. The at least one structured metallic layer may in particular be formed from the same material as the metallic substrate and, after application to the latter, form a lead frame comprising a plurality of metallic regions with the metallic substrate. The at least one structured metallic layer is applied in particular to the first side, i.e. to the side on which the first cavity is formed, and is arranged in particular at least partially on the mold compound.

By such a method, a leadframe substrate with several metallic areas can be produced in several steps or layer by layer, which comprises at least one first leadframe layer with a first metallic area and at least one second metallic area spaced therefrom. The first and second metallic regions are separated from one another by a first cavity on a first side of the first leadframe layer and a second cavity on a second side of the first leadframe layer opposite the first side. The at least one electrical component is arranged in the first cavity in such a way that it electrically connects the first metallic region and the at least one second metallic region to one another and is embedded in a mold compound. According to a first embodiment example, at least one optoelectronic component can be arranged on a second side of the first leadframe layer facing away from the first cavity and electrically connect the first metallic region and the second metallic region to one another. Alternatively, according to a second embodiment example, at least one structured metallic layer, in particular a second leadframe layer, can be arranged on the first side of the first leadframe layer, which has metallic regions, some of which are in electrically conductive connection with, for example, the first metallic region or the second metallic region. The second leadframe layer can also have metallic regions which are not in electrically conductive connection with metallic regions of the first and second leadframe layers, for example a third metallic region. The at least one optoelectronic component can then be arranged on a side of the second leadframe layer facing away from the first cavity and electrically connect the first metallic region and, for example, the third metallic region to one another.

In some embodiments, the step of applying the structured metallic layer is performed prior to the step of arranging the at least one optoelectronic component, wherein the at least one optoelectronic component is arranged on metallic regions of the structured metallic layer.

In some embodiments, the at least one optoelectronic component electrically interconnects the first metallic region and a third metallic region, wherein the third metallic region is formed by a region of the structured metallic layer.

In some embodiments, the step of arranging the at least one electrical component in the first cavity comprises wire bonding. However, the step of arranging the at least one electrical component may also comprise bonding or soldering the at least one electrical component onto the first metallic region and the at least one second metallic region. This can be arranged on a respective bond pad on the first metallic area and the second metallic area and electrically connected to these.

In some embodiments, the step of creating at least one second cavity comprises an etching process. In particular, the second cavity is created after the step of arranging the at least one electrical component in the first cavity or after molding the at least one electrical component in the first cavity. In particular, the second cavity is produced or etched in such a way that the underlying electrical component or mold compound is not damaged by the production of the second cavity, but a first metallic region and at least one second metallic region spaced apart therefrom are produced, which are separated from one another by the at least one first cavity and the at least one second cavity. For this purpose, the substrate can be structured or etched from a second side opposite the first side, for example, in such a way that material of the substrate is removed up to the first cavity or up to the mold compound.

In some embodiments, the step of applying the structured metallic layer comprises a sputtering of a seed layer, a subsequent galvanic application of a metallic layer, such as copper, and a subsequent structuring of the metallic layer by means of, for example, photolithography.

### BRIEF DESCRIPTION OF THE DRAWINGS

In the following, embodiments of the invention are explained in more detail with reference to the accompanying drawings.

FIG. 1 shows steps of a method for manufacturing an optoelectronic device;

FIG. 2 shows a method step for manufacturing an optoelectronic device according to some aspects of the proposed principle;

FIG. 3 shows further method step for manufacturing an optoelectronic device according to some aspects of the proposed principle;

FIGS. 4A and 4B show method steps for manufacturing an optoelectronic device according to some aspects of the proposed principle;

FIGS. 5A and 5B show method steps for manufacturing an optoelectronic device according to some aspects of the proposed principle;

FIGS. 6A and 6B show method steps for manufacturing an optoelectronic device according to some aspects of the proposed principle;

FIGS. 7A and 7B show two embodiments of an optoelectronic device according to some aspects of the proposed principle;

FIGS. 8A and 8B show method steps for manufacturing an optoelectronic device according to some aspects of the proposed principle;

FIGS. 9A and 9B show two further embodiments of an optoelectronic device according to some aspects of the proposed principle;

FIG. 10A shows a further embodiment of an optoelectronic device according to some aspects of the proposed principle; and

FIG. 10B shows a top view of another embodiment of an optoelectronic device according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

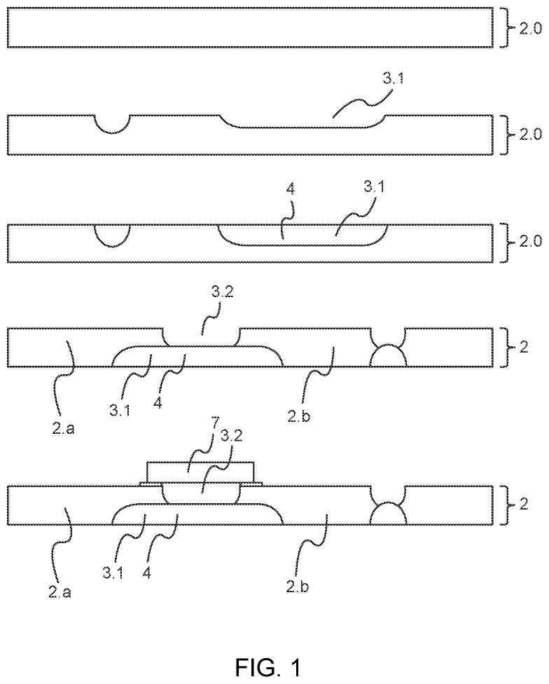

FIG. 1 shows steps of a method for manufacturing an optoelectronic device shown in the lower image of the figure. The optoelectronic device comprises a lead frame 2, with a first metallic region 2.a and a second metallic region 2.b, which are separated from each other by a first cavity 3.1 on a first side of the lead frame 2 and by a second cavity 3.2 on a second side of the lead frame 2. The metallic areas are mechanically held together by a mold compound 4, which is arranged at least in the first cavity 3.1. An optoelectronic component 7, which electrically connects the first and second metallic areas 2.a, 2.b to each other, is arranged on the lead frame 2 on a side of the lead frame opposite the first cavity.

Steps in the manufacture of such an optoelectronic device are shown in the figure in sequence from top to bottom. In a first step, a metallic substrate 2.0 is provided, into which at least a first cavity 3.1 is introduced from a first side of the substrate 2.0, for example by means of an etching process. The cavity is then filled by means of a mold compound and, in a further step, at least one second cavity 3.2 is introduced from a second side of the substrate 2.0 opposite the first side, for example also by means of an etching process. The second cavity is formed opposite the first cavity and extends through the substrate to the first cavity, so that the substrate is divided by the two cavities into the first and second metallic areas 2.a, 2.b, thus forming the lead frame 2.

The optoelectronic component 7 is then arranged on the lead frame in such a way that it is arranged on a side of the lead frame facing away from the cavity and electrically connects the first and second metallic areas to each other. However, such an optoelectronic device has the disadvantage that a more complex interconnection is practically impossible.

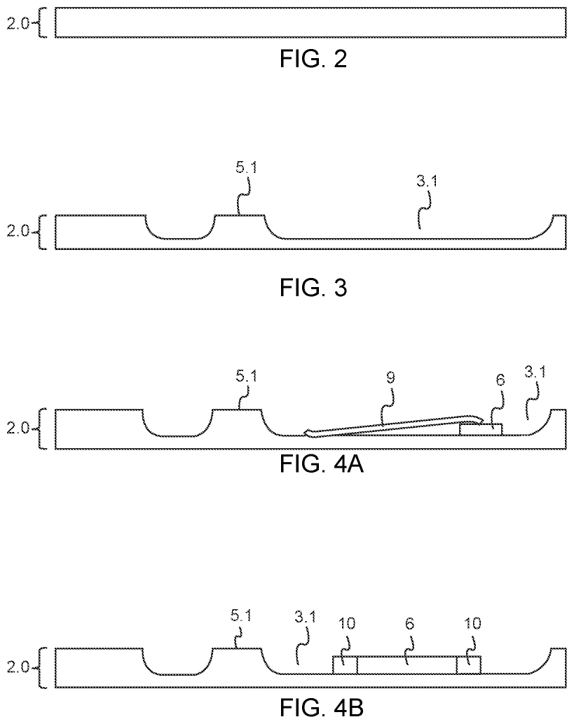

The present invention therefore provides an optoelectronic device that enables more complex interconnection by means of electrical components embedded in the mold compound. This allows additional functions, such as an ESD diode or a series resistor, to be integrated into the lead frame or the mold compound of the lead frame. FIGS. 2 and 3 show first process steps for manufacturing such an optoelectronic device according to some aspects of the proposed principle.

In a first step, as shown in FIG. 2, a metallic substrate 2.0 is provided and at least a first cavity 3.1 is formed on a first side 5.1 of the metallic substrate 2.0, for example by etching. An electrical component 6 is then arranged in the first cavity 3.1 as shown in FIGS. 4A and 4B. As shown in FIG. 4A, the electrical component 6 can either be arranged in the cavity by means of a wire bonding process and thus comprise a bonding wire 9, or can be arranged in the first cavity 3.1 on bonding pads or solder pads 10 and electrically connected thereto. The electrical component 6 can be an ESD protection diode (FIG. 4A) or a series resistor (FIG. 4B), as in the examples shown in FIG. 4A and 4B.

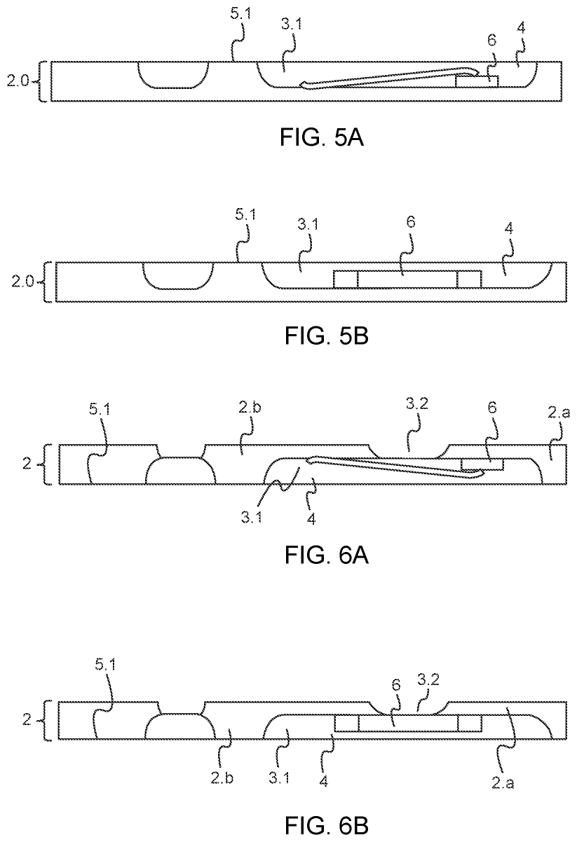

In a further step according to FIGS. 5A and 5B, the respective electrical component 6 is molded by means of a mold compound 4, so that the first cavity 3.1 of the embodiments shown in each of the two figures is filled with the mold compound 4 and is substantially flush with the first side 5.1 of the metallic substrate 2.0.

The component is then rotated and, as shown in FIGS. 6A and 6B, at least one second cavity 3.2 is introduced on a side of the metallic substrate 2.0 opposite the first cavity, for example by means of etching. The second cavity 3.2 is formed opposite the first cavity 3.1 and extends through the metallic substrate 2.0 up to the first cavity or up to the mold compound 4, so that the metallic substrate 2.0 is divided by the two cavities into the first and second metallic areas 2.a, 2.b, thus forming the lead frame 2. When creating the second cavity, particular care must be taken to form the second cavity 3.2 in such a way that the first and second metallic areas 2.a, 2.b are created separately from each other, but the electrical component 6 is not damaged as a result.

In a further step, an optoelectronic component 7 is arranged on a second side 5.2 of the lead frame 2 facing away from the first cavity 3.1 in such a way that it electrically connects the first metallic region 2.a and the second metallic region 2.b. In the case shown, the second side 5.2 facing away from the first cavity 3.1, on which the optoelectronic component 7 is arranged, forms a first outer side 8.1 of the lead frame and the first side 5.1 of the lead frame forms a second outer side 8.2 of the lead frame.

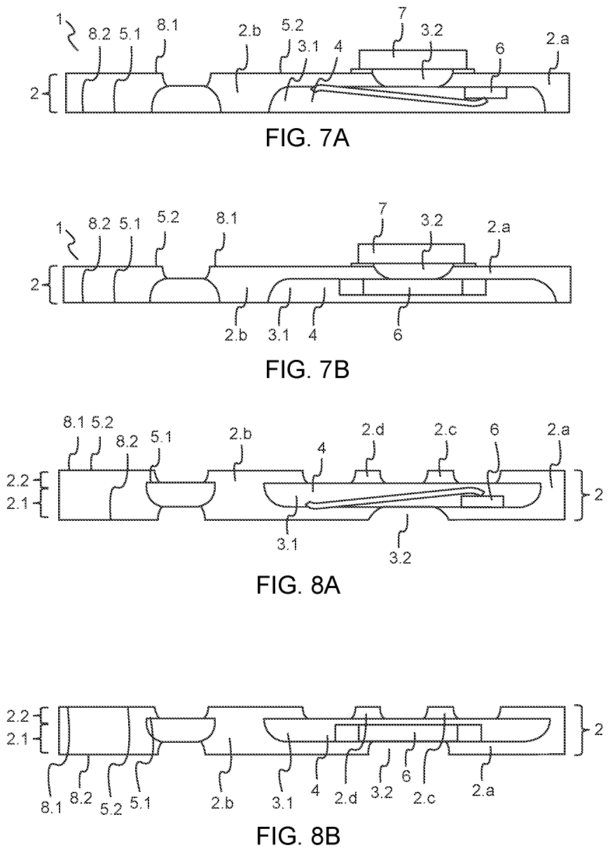

The optoelectronic device 1 created using these process steps is shown in the form of two embodiments in FIGS. 7A and 7B. The only difference between them is a different electrical component 6, which is arranged in the first cavity and molded using the mold compound 4.

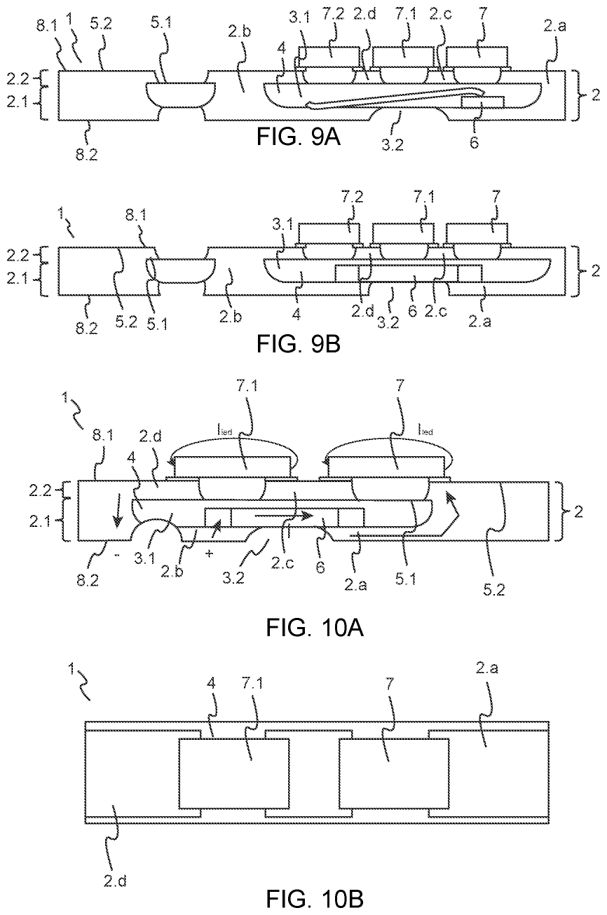

FIGS. 9A and 9B show two alternative embodiments of an optoelectronic device 1 according to some aspects of the proposed principle. For their manufacture, following the step of introducing a second cavity 3.2 as shown in FIGS. 6A and 6B, a structured metallic layer 2.2 is applied to the first side 5.1 of the leadframe (also referred to as first leadframe layer 2.1) present up to that point. The structured metallic layer or further leadframe layer 2.2 comprises metallic areas, some of which are in electrically conductive contact with, for example, the first metallic area 2.a and the second metallic area 2.b of the first leadframe layer 2.1. The second leadframe layer 2.2 also comprises metallic regions which are not in electrically conductive contact with metallic regions of the first and second leadframe layers, but are arranged on the mold compound 4 in an electrically insulated manner, for example a third metallic region 2.c and a fourth metallic region 2.d.

An optoelectronic component 7 or several optoelectronic components 7, 7.1, 7.2 are then arranged on a side of the second leadframe layer 2.2 facing away from the first cavity 3.1, in particular the second side 5.2 of the leadframe 2, and electrically connect, for example, the first metallic region 2.a and the third metallic region 2.c or the third metallic region 2.c and the fourth metallic region 2.d, as well as the fourth metallic region 2.d and the second metallic region 2.b to one another. In the illustrated case, compared to the previous embodiments, the first side 5.1 of the lead frame is not formed by an outer side of the lead frame, but rather by the intermediate surface between the first and the second lead frame layer 2.1, 2.2, whereas the second side 5.2 of the lead frame 2 forms the first outer side 8.1 of the lead frame in the same way.

By applying the second leadframe layer 2.2 to the first cavity 3.1, this forms a cavity, so to speak, which extends from the first side 5.1 of the leadframe 2 in the direction of a second 8.2 opposite the first 8.1 on the outside of the leadframe 2 and is filled with the mold compound 4.

Both in the embodiment examples of FIGS. 7A and 7B and in the embodiment examples of FIGS. 9A and 9B, the optoelectronic component 7 or the optoelectronic components 7, 7.1, 7.2 are connected in parallel with the electrical component 6 when a voltage is connected to the first and second metallic regions 2.a, 2.b. An alternative embodiment is shown in FIG. 10A, which has such an arrangement of the metallic regions that the optoelectronic components 7, 7.1 are connected in series with the electrical component 6 when a voltage is connected to the second and a fourth metallic region 2.b, 2.d. This is shown as an example by the two symbols “+” and “−”. The applied voltage enables a current flow I through the electrical component 6 and a current flow I_{led} through each of the optoelectronic components.

FIG. 10B shows a top view of the optoelectronic device 1 shown in FIG. 10A. It can also be seen in the top view that the third metallic region 2.c is arranged at a distance from the first or a fourth metallic region 2.a, 2.d and is not electrically connected to these, except via the optoelectronic components 7, 7.1. It can also be seen that the mold compound 4 surrounds the individual metallic areas and thus mechanically connects them to each other.

### REFERENCE LIST

1 Optoelectronic device
2 Leadframe
2.1 Lead frame layer
2.2 Lead frame layer
2.a First metallic region
2.b second metallic region
2.c Third metallic region
2.d Fourth metallic region
3.1 First cavity
3.2 Second cavity
4 Mold compound
5.1 First side
5.2 Second side
6 Electrical component
7, 7.1, 7.2 Optoelectronic component
8.1 First outer side
8.2 Second outer side
9 Bonding wire
10 Bond pad, Solder pad

1.-17. (canceled)

18. An optoelectronic device comprising:
a lead frame with a first metallic region and at least one second metallic region spaced therefrom, wherein the first metallic region and the at least one second metallic region form a first cavity on a first side of the lead frame;
at least one electrical component, which is arranged in the first cavity and molded with a mold compound, and which electrically connects the first metallic region and the at least one second metallic region to one another; and
at least one optoelectronic component, which electrically connects the first metallic region and the second metallic region on a second side of the lead frame facing away from the first cavity; or
at least one optoelectronic component, which electrically connects the first metallic region and a third metallic region on a second side of the lead frame facing away from the first cavity,
wherein the second side is formed by a first outer side of the lead frame and the first side is formed by a side lying within the lead frame, and
wherein the first cavity is formed by a cavity, which extends from the first side of the lead frame in a direction of a second outer side of the lead frame opposite the first outer side.

19. The optoelectronic device according to claim 18, wherein the mold compound mechanically connects the first and the at least one second metallic region to one another.

20. The optoelectronic device according to claim 18, wherein the mold compound fills the first cavity and is substantially flush with the first side of the lead frame.

21. The optoelectronic device according to claim 18, wherein the electrical component comprises at least one of a series resistor, an ESD protection diode, an RFID chip, or an integrated circuit.

22. The optoelectronic device according to claim 18, wherein the first and second sides are formed by two opposite outer sides of the lead frame.

23. The optoelectronic device according to claim 18, wherein the third metallic region is arranged on the mold compound at a distance from the first metallic region.

24. The optoelectronic device according to claim 23, further comprising:
a fourth metallic region arranged at a distance from the third metallic region; and
a further optoelectronic component electrically connecting the third metallic region and the fourth metallic region to one another.

25. The optoelectronic device according to claim 18, wherein the at least one electrical component and the at least one optoelectronic component are connected in series with one another.

26. The optoelectronic device according to claim 18, wherein the at least one electrical component and the at least one optoelectronic component are connected in parallel with one another.

27. The optoelectronic device according to claim 18, further comprising a first contact surface and a second contact surface on the second outer side of the lead frame opposite the second side, via which the optoelectronic device is electrically connectable.

28. The optoelectronic device according to claim 18, wherein the at least one electrical component electrically connects the first metallic region and the at least one second metallic region to one another via a bonding wire.

29. A method for manufacturing an optoelectronic device, the method comprising:
providing a metallic substrate with at least one first cavity on a first side of the substrate;
arranging at least one electrical component in the first cavity;
molding the at least one electrical component in the first cavity with a mold compound;
creating at least one second cavity on a second side of the substrate opposite the first side such that a first metallic region and at least one second metallic region spaced therefrom are formed by the at least one first cavity and the at least one second cavity, and wherein the at least one electrical component electrically connects the first metallic region and the at least one second metallic region to one another;
arranging at least one optoelectronic component on at least the first metallic region such that the at least one optoelectronic component electrically connects the first metallic region and at least one of the second or a third metallic region to one another; and
applying a structured metallic layer on the first side of the substrate, wherein the structured metallic layer comprises at least one electrically insulated region.

30. The method according to claim 29, wherein applying the structured metallic layer is conducted before arranging the at least one optoelectronic component, and wherein the at least one optoelectronic component is arranged on regions of the structured metallic layer.

31. The method according to claim 29, wherein the at least one optoelectronic component electrically connects the first metallic region and the third metallic region to one another, and wherein the third metallic region is formed by a region of the structured metallic layer.

32. The method according to claim 29, wherein arranging the at least one electrical component in the first cavity comprises wire bonding.

33. The method according to claim 29, wherein creating the at least one second cavity comprises an etching process.

34. The method according to claim 29, wherein applying the structured metallic layer comprises at least one of sputtering, electrodeposition of a metallic layer or a photolithography process.
